(19) United States
(12) Patent Application Publication
(10) Pub. No.: US 2013/0229199 A1
(43) Pub. Date: Sep. 5, 2013

(54) TESTING APPARATUS FOR PERFORMING AVALANCHE TEST

(71) Applicant: CHOON LEONG LOU, HSINCHU CITY (TW)

(72) Inventor: CHOON LEONG LOU, HSINCHU CITY (TW)

(73) Assignee: STAR TECHNOLOGIES, INC., HSINCHU CITY (TW)

(21) Appl. No.: 13/412,135

(22) Filed: Mar. 5, 2012

(51) Int. Cl. G01R 31/26

(52) U.S. Cl. 324/756.01

(57) ABSTRACT

A testing apparatus for performing an avalanche test includes a wafer chuck configured to retain a wafer having a plurality of transistors, wherein the wafer chuck includes an insulating body and a plurality of conductors embedded in the insulating body. In one embodiment of the present invention, the device holder includes a plurality of conductors having horizontal sides and longitudinal sides, a plurality of insulating horizontal lines positioned at the horizontal sides, and a plurality of insulating longitudinal lines positioned at the longitudinal sides and intersecting the horizontal lines.

### BACKGROUND OF THE INVENTION

1. Technical Field

The present invention relates to a testing apparatus for performing an avalanche test, and more particularly, to a testing apparatus for performing an avalanche test on transistors at the wafer level.

2. Background

Generally, it is necessary to test the electrical characteristics of integrated circuit devices at the wafer level to verify the performance of the integrated circuit device and to confirm whether the device satisfies the product specification. Integrated circuit devices with electrical characteristics satisfying the specification are selected for the subsequent packaging process, while the other devices are discarded to avoid incurring additional packaging cost. Another electrical property test is performed on the integrated circuit device after the packaging process is completed in order to screen out any substandard devices and increase the product yield.

To avoid incurring additional packaging cost, the avalanche test can be performed at the wafer level, rather than after the packaging process as in the prior art, so as to discard any devices not complying with the avalanche specification before the packaging process. FIG. 1 illustrates the avalanche test of the transistors at the wafer level according to prior art. A wafer chuck 11 is configured to retain a wafer 21 having a plurality of transistors 23 having a drain terminal 25, a gate terminal 27 and a source terminal 29. The drain terminal 25 and the gate terminal 27 are connected to power sources 35 and 37 such as the voltage source or current source, and the source terminal 29 are connected to an power source 39 such as the voltage source or current source through a contact 13 of the wafer chuck 11.

U.S. Pat. No. 7,368,934 discloses an avalanche test circuit for applying an avalanche test signal to an integrated circuit device under test after the packaging process. The avalanche test circuit comprises a series combination of a voltage source and an inductance; a switching device connected in parallel with said series combination; a diode for being connected to a test terminal of said device under test, said diode being connected to a connection point of said inductance and said switching device;

and a common terminal of said device under test being connected to a connection point of said switching device and said voltage source.

### SUMMARY

One aspect of the present invention provides a testing apparatus for performing an avalanche test on the integrated circuit devices at the wafer level.

In one embodiment of the present invention, a testing apparatus for performing an avalanche test comprises a wafer chuck configured to retain a wafer having a plurality of transistors, wherein the wafer chuck comprises an insulating body and a plurality of conductors embedded in the insulating body.

In one embodiment of the present invention, a testing apparatus for performing an avalanche test comprises a device holder configured to retain a wafer having a plurality of transistors, wherein the device holder comprises a plurality of conductors having horizontal sides and longitudinal sides; a plurality of insulating horizontal lines positioned at the horizontal sides; and a plurality of insulating longitudinal lines positioned at the longitudinal sides and intersecting the horizontal lines.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 illustrates a testing apparatus for performing an avalanche test of the transistors at the wafer level according to prior art;

FIGS. 2 and 3 illustrate a testing apparatus for performing an avalanche test according to one embodiment of the present invention; and

FIG. 4 illustrates the structure of a device holder according to another embodiment of the present invention.

### DETAILED DESCRIPTION

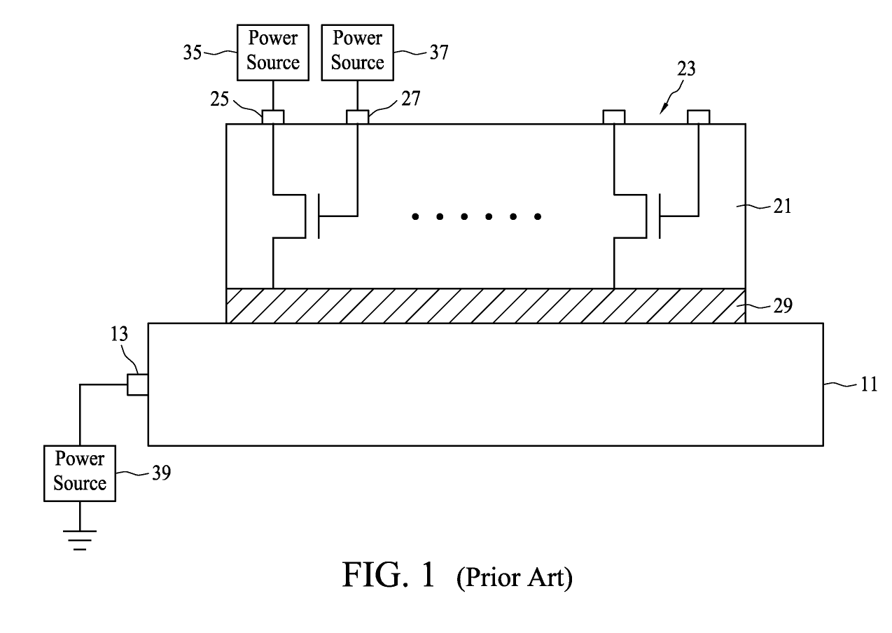

However, in the prior art shown in FIG. 1, one major problem with conducting the avalanche test at the wafer level is that, because the devices (transistors 23) formed on the wafer 21 have a common source 29, the wafer 21 is placed on the chuck 11 during the wafer level testing, and the wafer chuck 21 acts as a large capacitor such that the current passing through the device under test cannot flow to the current meter of the tester.

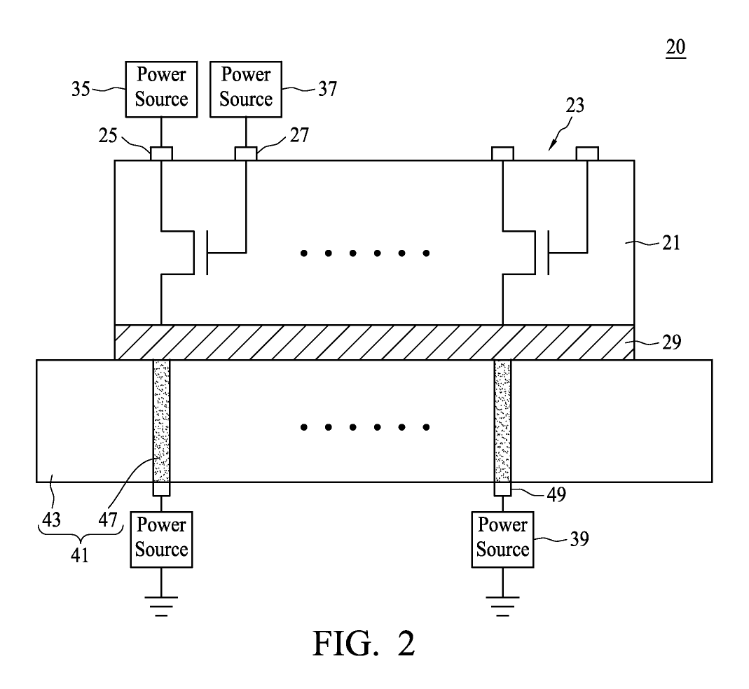

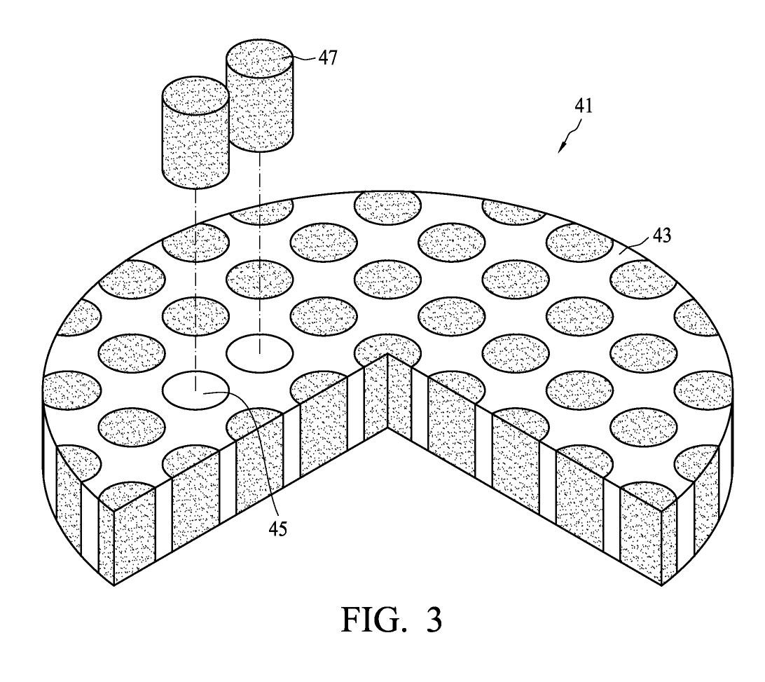

FIGS. 2 and 3 illustrate a testing apparatus 20 for performing an avalanche test according to one embodiment of the present invention. In one embodiment of the present invention, the testing apparatus 20 comprises a device holder such as the wafer chuck 41 configured to retain a wafer 21 having a plurality of transistors 23 each having a drain terminal 25, a gate terminal 27 and a source terminal 29. The drain terminal 25 and the gate terminal 27 are connected to power sources 35 and 37 such as the voltage source or current source, and the source terminal 29 are connected to an power source such as the voltage source or current source through a contact 49 of the wafer chuck 41.

In one embodiment of the present invention, the device holder 41 comprises an insulating body 43 and a plurality of conductors 47 embedded in the insulating body 43. In one embodiment of the present invention, the insulating body 43 has a plurality of holes 45, and the conductors 47 are embedded in the holes 45. In one embodiment of the present invention, the conductors 47 are positioned in an array manner. In one embodiment of the present invention, the wafer 21 includes a plurality of drain terminals 29, the position of the conductors 47 corresponds to the position of the drain terminals 25 of the wafer 21.

In the prior art, because the wafer chuck acts as a large capacitor, the current passing through the common source terminal 29 of the transistor 23 is distributed to the wafer chuck 11 rather than flowing to the meter, and the detector detects no current peak. In contrast, in one embodiment of the present invention, by dividing the device holder (wafer chuck) 41 into the plurality of conductors 47 such that the device holder (wafer chuck) 41 does not act as a large capacitor, the current passing through the common source terminal 29 of the transistor 23 flows to the power source (serving as a meter) 39 without distributing to the device holder (wafer chuck) 41. Consequently, the present testing apparatus 20 can accurately measure the current peak on the common source terminal 29 of the transistor 23 during the avalanche test of the transistors at the wafer level.

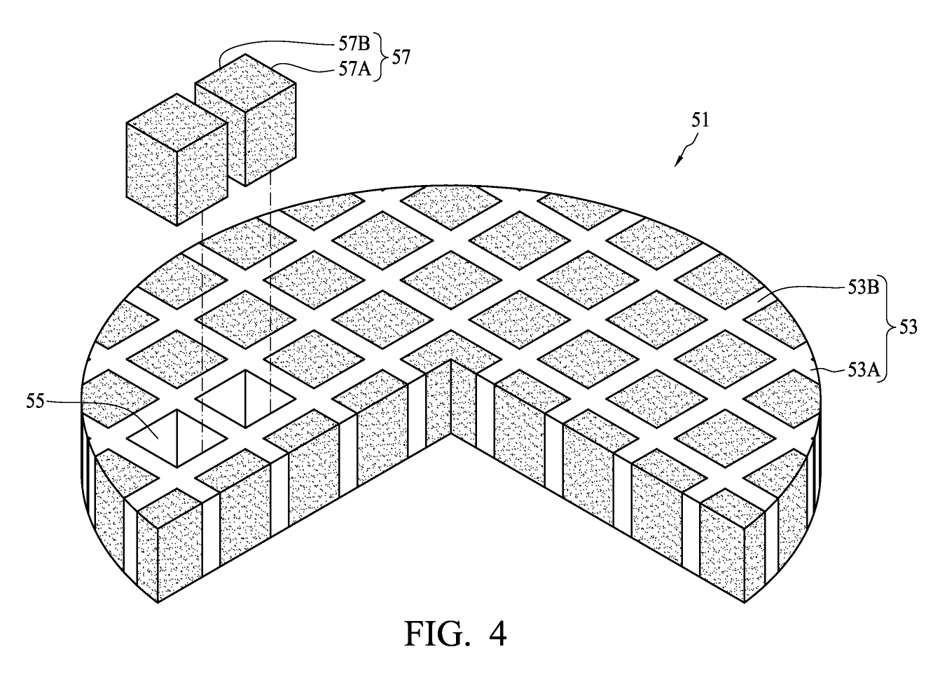

FIG. 4 illustrates the structure of a device holder 51 according to another embodiment of the present invention. In one embodiment of the present invention, the device holder 51 comprises a plurality of conductors 57 having horizontal sides 57A and longitudinal sides 57B, a plurality of insulating horizontal lines 53A positioned at the horizontal sides 57A, and a plurality of insulating longitudinal lines 53B positioned at the longitudinal sides 57B and intersecting the horizontal lines 53A. In one embodiment of the present invention, the horizontal lines 53A and the longitudinal lines 53B form a plurality of holes 55, and the conductors 57 are positioned in the holes 55.

In one embodiment of the present invention, the conductors 57 are positioned in an array manner, and the insulating horizontal lines 53A and the insulating longitudinal lines 53B form a grid structure. In one embodiment of the present invention, the wafer 21 includes a plurality of drain terminals 27, the position of the conductors 57 corresponds to the position of the drain terminals 27 of the wafer 21, and the power source (servicing as a meter) 39 is connected to the source terminal 29 of the transistor 23 through one of the conductors 57 of the device holder 51.

In the prior art, because the wafer chuck acts as a large capacitor, the current passing through the common source terminal 29 of the transistor 23 is distributed to the wafer chuck rather than flowing to the current meter 49, and the pulse detector 47 detects no current peak. In contrast, in one embodiment of the present invention, by dividing the device holder (wafer chuck) 51 into the plurality of conductors 57 such that the device holder (wafer chuck) 51 does not act as a large capacitor, the current passing through the common source terminal 29 of the transistor 23 flows to the current meter 49 without distributing to the device holder (wafer chuck) 51. Consequently, the present testing apparatus can accurately measure the current peak on the common source terminal 29 of the transistor 23 during the avalanche test of the transistors at the wafer level.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A testing apparatus for performing an avalanche test, comprising a wafer chuck configured to retain a wafer having a plurality of transistors, wherein the wafer chuck comprises an insulating body and a plurality of conductors embedded in the insulating body.

2. The testing apparatus for performing an avalanche test of claim 1, wherein the conductors are arranged in an array manner.

3. The testing apparatus for performing an avalanche test of claim 1, wherein the wafer includes a plurality of terminals on an upper surface, and the position of the conductors of the wafer chuck corresponds to the position of the terminals of the wafer.

4. The testing apparatus for performing an avalanche test of claim 1, wherein each of the transistors comprises a first terminal on an upper surface of the wafer, a second terminal on the upper surface of the wafer and a third terminal on a bottom surface of the wafer.

5. The testing apparatus for performing an avalanche test of claim 4, further comprising a first power source connected to the first terminal.

6. The testing apparatus for performing an avalanche test of claim 4, further comprising a second power source connected to the second terminal.

7. The testing apparatus for performing an avalanche test of claim 4, further comprising a third power source connected to the third terminal.

8. A testing apparatus for performing an avalanche test, comprising a device holder configured to retain a wafer having a plurality of transistors, the device holder comprising:
a plurality of conductors having horizontal sides and longitudinal sides;
a plurality of insulating horizontal lines positioned at the horizontal sides; and
a plurality of insulating longitudinal lines positioned at the longitudinal sides and intersecting the horizontal lines.

9. The testing apparatus for performing an avalanche test of claim 8, wherein the conductors are arranged in an array manner.

10. The testing apparatus for performing an avalanche test of claim 8, wherein the insulating horizontal lines and the insulating longitudinal lines form a grid structure.

11. The testing apparatus for performing an avalanche test of claim 8, wherein the wafer includes a plurality of terminals on an upper surface, and the position of the conductors of the device holder corresponds to the position of the terminals of the wafer.

12. The testing apparatus for performing an avalanche test of claim 8, wherein each of the transistors comprises a first terminal on an upper surface of the wafer, a second terminal on the upper surface of the wafer and a third terminal on a bottom surface of the wafer.

13. The testing apparatus for performing an avalanche test of claim 12, further comprising a first power source connected to the first terminal.

14. The testing apparatus for performing an avalanche test of claim 12, further comprising a second power source connected to the second terminal.

15. The testing apparatus for performing an avalanche test of claim 12, further comprising a third power source connected to the third terminal.
